(19) United States
(12) Patent Application Publication
(10) Pub. No.: US 2009/0314522 A1
(43) Pub. Date: Dec. 24, 2009

(54) Printed Circuit Board With Additional Functional Elements, Method of Production and Use

(76) Inventors: Rudolf Janesch, Gars am Kamp (AT); Erich Strummer, Gars am kamp (AT); Johann Hackl, Gars am Kamp (AT)

Correspondence Address: COOPER & DUNHAM, LLP, 30 Rockefeller Plaza, 20th Floor, NEW YORK, NY, 10112, US

(21) Appl. No.: 12/223,476

(22) PCT Filed: Jan. 16, 2007
(86) PCT No.: PCT/EP2007/000319

§ 371 Date: Dec. 29, 2008

(30) Foreign Application Priority Data
Jan. 31, 2006 (DE) 10 2006 004 322.7

(51) Int. Cl. H05K 1/02; H05K 1/09; B23K 20/10; B23K 20/12; B29C 65/08; B29C 65/06

(52) U.S. Cl. 174/252; 174/250; 174/257; 174/254; 228/110.1; 228/112.1; 156/73.1; 156/73.5

(57) ABSTRACT

The invention relates to a multifunctional printed circuit board comprising at least one additional functional element in the form of a round or rectangular conductor which is at least partially fastened on an electrically conducting strip conductor structure by ultrasound or friction welding in a mechanical and electrical and thermally conducting and planar manner and in such a fashion that an intermetal compound is formed. The invention also relates to a method for producing said printed circuit board, to its use as a wiring element for complex structures that is suitable for high current conduction and to uses for a specific thermal management.

The invention relates to a printed circuit board with additional functional elements, comprising round or rectangular electrically conductive wiring elements, that is to say additive conduction tracks, which are arranged on the two surfaces or in an inner layer of a printed circuit board. Integration both of current-loadable wiring elements and of areal elements of good thermal conductivity or areal elements of good flexibility is provided alongside a usually finely structured wiring.

Customary printed circuit boards are produced by means of etching technology, that is to say by means of a subtractive technology. In this case, essentially the respectively used copper film thickness of typically 35 μm or half or double thickness and the structure width limits the current-carrying capacity of the conductor tracks. By combining a conventional wiring level structured by etching technology with usually a small number of additive wiring elements it is possible to make a multifunctional printed circuit board which can be produced in a very cost-effective manner and which integrates a correspondingly current-carrying wiring in addition to the usually complex circuit logic.

Modern complex standard and precision printed circuit boards through to high-precision printed circuit boards are produced subtractively by means of etching technology according to the prior art, wherein subsequent chemical or electrolytic processes can bring about plated-through holes or the reinforcement of conductive structures. In this case, a copper-coated or else aluminum-coated substrate is masked photolithographically or by screen printing and this mask is hardened in such a way that the conductor structure can be produced by means of etching chemicals. The so-called etching mask is subsequently stripped.

As an alternative, use is made of additive structuring techniques in the form of applying electrically conductive pastes by means of screen printing. Inkjet- and laser-based additive techniques are also possible, although they can only be used to a limited extent since there is cost compatibility with respect to conventional etching technology only in special cases and, moreover, the technical parameters that can be obtained are significantly less favorable.

Copper-coated substrates having a copper thickness of typically 36 μm or half or double thickness are used in one customary printed circuit board technology. Electrodeposition of copper is often used as well. Wiring structures of very good conductivity can thus be produced.

Conductor track widths of less than 100 μm and conductor track spacings of likewise in the region of 100 μm are realized in highly complex circuits. Besides this highly complex wiring, however, in specific applications in the automotive sector or in industrial electronics and similar branches of industry, wiring elements are desired which are able not only to conduct signals and switching currents but are also able to conduct currents of from several amperes to a few 50 and 100 amperes and above. For such requirements, individual wiring elements are then produced from wires or stamped parts or so-called thick copper technology with circuit boards having copper films having a thickness of up to 400 μm is used.

The etching-technological structuring of such thick copper films is very complicated and inefficient in terms of costs since the majority of the copper actually has to be etched away.

EPO1004226B1 mentions a method for producing wire-written printed circuit boards by partially filling a curable insulating compound into a casting mold that is open at the top, which is not in any way necessary in the present invention.

WO02067642A1 mentions a method for producing a multiwire printed circuit board in which, on one side of a thin surface element composed of electrically conductive material, conductive wires are placed in a defined manner by means of interspaced adhesive surfaces and are electrically contact-connected at predetermined contact locations of the surface element by means of welding, bonding, soldering, conductive adhesive bonding or the like.

On the fixed conductive wires, a mechanical stabilization element is provided in the form of a prepreg or in the form of an electrically conductive or insulating surface element applied by means of an insulating film. In this case, the surface element is structured from the other side in such a way that the contact locations are separated from the rest of the surface element. Conductive wires are placed in a defined manner by means of adhesive surfaces.

In the document mentioned there is the disadvantage that the conductive wires that are inherently profiled in round fashion are electrically conductively connected to the remaining parts of the printed circuit board with the aid of a welded joint or a bonding connection. However, this is associated with the disadvantage that a relatively thin and round wire cross section can be contact-connected only at points on a large-area metalized copper plate. This leads to high temperatures at the contact location and a corresponding thermal loading in the region of the printed circuit board, which leads to warpages in the region of the copper film and also in the region of the surrounding plastic materials.

The printed circuit board therefore tends toward warpage at said contact locations, and a planar surface of the board is no longer afforded during subsequent photolithographic processing of the board. This is associated with the disadvantage that fine structures cannot be applied to the surface of the printed circuit board in a manner free of faults. The reject rate is thus very high.

The object of the present invention is the cost-effective production of multifunctional printed circuit boards for the wiring of highly complex conductor structures, in particular precision to high-precision conductor structures, together with structures for conducting relatively high currents on a circuit board.

This aim is achieved by fitting functional elements by means of friction welding or ultrasound onto one or onto both surfaces and/or in an inner layer of an as yet unstructured copper film and/or an already structured printed circuit board and the subsequent leveling process in the form of a coating and/or lamination.

The invention accordingly relates to a printed circuit board comprising additional functional elements. A highly complex fine structure on a printed circuit board with the possibility of wiring high-current-carrying components on a circuit board is described in this case.

Furthermore, a description is given of the dissipation of heat by the formation of such additional elements on and/or in a printed circuit board and the application thereof for the contact-connection of components for the purpose of dissipating heat.

In a first embodiment variant, electrically conductive wiring elements are fixed by means of friction welding methods or ultrasonic welding methods preferably areally onto a conductor structure that is situated underneath and produced by etching technology, and are subsequently processed in leveling fashion by means of corresponding resin systems.

In a second embodiment variant, electrically conductive wiring elements are fixed by means of friction welding or ultrasound in insulating fashion on a printed circuit board substrate. In this case, the insulation layer can be arranged over the whole area or selectively on the corresponding printed circuit board surface or the electrically conductive wiring element can be provided with a corresponding resin on the corresponding side or in enveloping fashion. An independent wiring level is produced in this way. The subsequent leveling by means of suitable resin systems can be effected as in the first embodiment variant.

In a further embodiment of the present invention, flat wiring elements, in particular, are used as selective heat-dissipating elements. In this case, areal elements are positioned into an inner layer or on one of the two surfaces and, after the leveling or lamination, an opening is produced in such a way that the respective component can be mounted in direct thermally conductive contact.

In a further embodiment, the preferably areal elements are arranged on or in a printed circuit board with subsequent leveling. This at least one areal element is selectively uncovered after a corresponding milling or scribing process by means of mechanical tools or by means of a laser in such a way that the element is flexible in the largely uncovered region and a semiflexible printed circuit board or a flexible printed circuit board is provided.

An electrically conductive wiring element—or an areal element of good thermal conductivity—or an areal element of good flexibility—is understood to mean piecewise elements in the form of round wire or flat wire, wherein copper or aluminum or a readily electrically conductive, flexible and contact-connectable alloy can be used as material.

In the case of an element of good thermal conductivity, said materials and also electrically insulating materials are used. In the case where said element is used as a flexural element, it is possible to use all of said materials and in addition readily processable areal materials that are sufficiently stable for the bending cycle number respectively required. Moreover, round or flat wires of this type can be embodied as coated in an adhesion-promoting manner or in a passivating manner or in an insulating manner.

A cost-effective method for producing a printed circuit board comprising additional functional elements is thus described. In this case, in particular round or rectangular electrically conductive wiring elements or areal elements of good thermal conductivity or areal elements of good flexibility are arranged by means of friction welding or ultrasound or thermocompression onto one or both surfaces and/or in an inner layer of a printed circuit board and a leveling process in the form of a coating and/or a lamination is subsequently performed.

The application of such a printed circuit board comprising additional functional elements as a multifunctional printed circuit board is described. Both the integration of a highly complex, finely structured printed circuit board with the possibility of wiring high-current-carrying components in a circuit board and the dissipation of heat by the formation of such additional elements on and/or in a printed circuit board are described here. The application of such additional elements for the production of semiflexible to rigid-flexible printed circuit boards is furthermore described.

In one development of the invention, the functional elements can be used as selective heat-dissipating elements.

It has now been found in the present invention that apparatuses of little complexity can be used to apply reinforcing wires or rectangular tracks, in particular in the form of flat wire elements, on a copper structure that has already been produced by etching technology according to the prior art or on a copper film that has not yet been etched. In this case, the etching-technological structures or the copper surface that has not yet been etched are or is used as adhesion elements and the additional elements are preferably areally contact-connected with good electrical and thermal conductivity and, of course, mechanical adhesion by means of friction welding or ultrasound. This process is preferably performed areally since a surface that is as planar as possible is required in order to be able to carry out subsequent leveling.

In principle, it is also possible to effect a contact-connection by means of current and in this case the planarity must be taken into account very carefully since, at the relatively high currents, high temperatures arise at points. This gives rise to thermal stresses that produce warpages. However, a subsequent mechanical or thermomechanical embossing process can provide a remedy here as well.

The computer-aided placement of these reinforcing elements is usually followed by a leveling process in the form of a doctor blade process or a screen printing process or a roller coating process or a computer-aided dispenser process. The leveling process can be realized in addition to or instead of a laminating process. In this case, it is possible to use correspondingly formed prepregs or conforming deformable and also, if appropriate, already structured layers. A surface that is as planar as possible is thus intended to be obtained. In this case, the lamination is typically effected between pressing plates in a hot-cold transfer press with or without vacuum assistance or—less customary—in an autoclave press.

If the at least one additional functional element is fitted only on the surface of a printed circuit board, the lamination process can be omitted.

According to the invention it has now been established that the contacts for such current-conductive elements are predetermined best by the electrically conductive structure and geometrically significantly wider contact areas can perfectly well be formed. A very good contact-connection of the printed circuit board is provided as a result. In addition, the additional functional elements can bring about a type of transposition of conductor tracks situated underneath, wherein it is necessary to take account of a corresponding insulation in these cases.

In a further embodiment of the present invention it has been established that such additional elements have very good thermally conductive selective properties and can be fitted locally where the intention is to fix components that produce a high power loss and a large amount of heat. The additional functional element can be arranged superficially on the printed circuit board and the corresponding component can then be arranged or mounted directly and with good thermal conductivity on the surface of said functional element.

However, the functional element can likewise be arranged in the interior of a printed circuit board. In this case, a cavity is milled or produced by laser technology or scribing technology and the corresponding component is then mounted with good thermal contact onto the uncovered surface of said functional element. Depending on the embodiment, the functional element is uncovered at least on an element basis and requires—in the case of copper, for example—passivation. Care must be taken to ensure that said passivation has good thermally conductive properties. This can be effected by pastes of good thermal conductivity, wherein the latter can be embodied in adhesive or solderable or detachable fashion. A chemical surface treatment or a preferably lead-free hot air tin-coating can also be effected.

All specifications and features disclosed in the documents, including the abstract, in particular the embodiment illustrated in the drawings, are claimed as essential to the invention insofar as they are novel individually or in combination with respect to the prior art.

The invention will now be described in more detail on the basis of a plurality of exemplary embodiments. In this case, further advantages and features will become apparent from the drawings and their description.

In the figures here:

FIG. 1 shows a schematic illustration of a multifunctional printed circuit board (1) according to the invention comprising a functional element (3) in a simple embodiment in section,

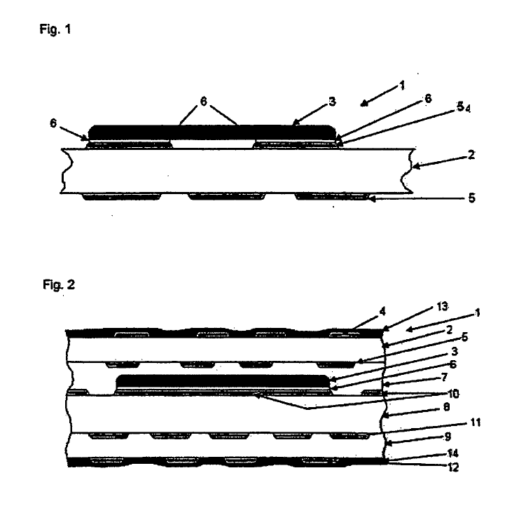

FIG. 2 shows a schematic illustration of a multifunctional printed circuit board (1) according to the invention comprising a functional element (3) in an inner layer in section,

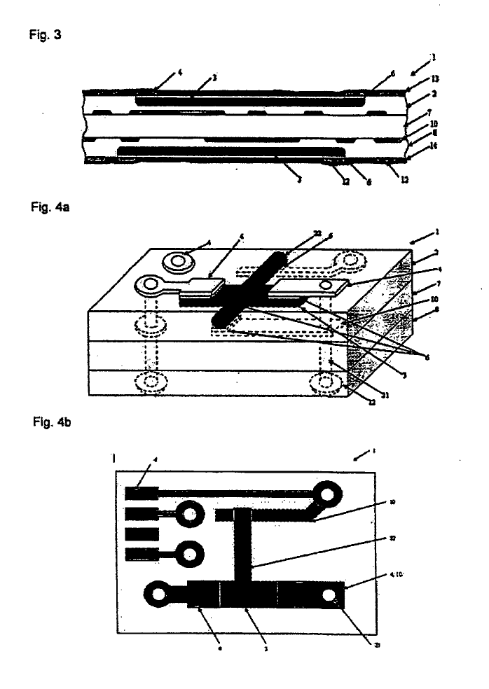

FIG. 3 shows a schematic illustration of a multifunctional printed circuit board (1) according to the invention comprising two functional elements (3) in section,

FIG. 4a shows a schematic illustration of a multifunctional printed circuit board (1) according to the invention comprising functional elements (3, 22, 23) in an oblique view,

FIG. 4b shows a schematic illustration of a multifunctional printed circuit board (1) according to the invention comprising functional elements (3, 22, 23) in a plan view,

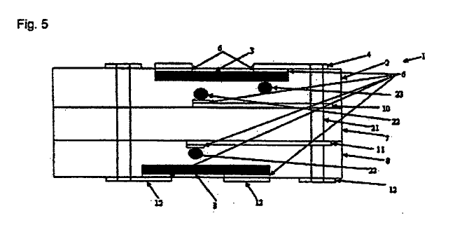

FIG. 5 shows a schematic illustration of a multifunctional printed circuit board (1) according to the invention comprising functional elements (3, 22, 23) in section,

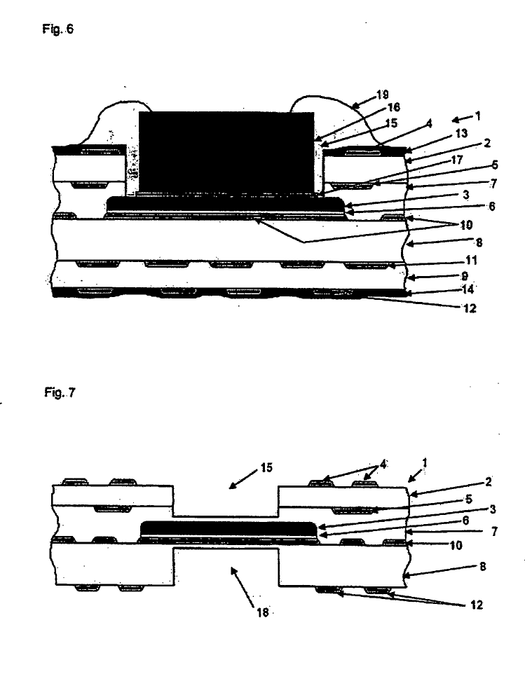

FIG. 6 shows a schematic illustration of a multifunctional printed circuit board (1) according to the invention comprising a functional element (3) with a mounted component (16) in section,

FIG. 7 shows a schematic illustration of a multifunctional printed circuit board (1) according to the invention comprising a functional element (3) with a cavity (15, 18) on both sides, in section,

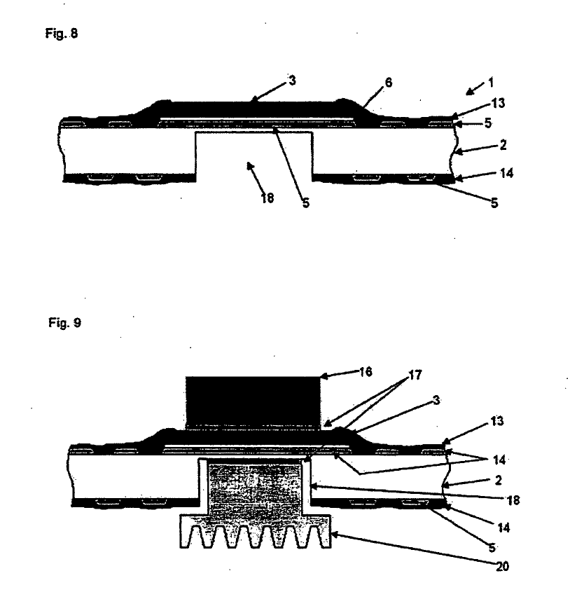

FIG. 8 shows a schematic illustration of a multifunctional printed circuit board (1) according to the invention comprising a functional element (3) with a cavity (18) on one side, in section,

FIG. 9 shows a schematic illustration of a multifunctional printed circuit board (1) according to the invention comprising a functional element (3) with a component (16) and a cavity (18) with inserted heat sink (20) in section.

FIG. 1 shows a schematic illustration of a multifunctional printed circuit board (1) according to the invention comprising a functional element (3) in a simple embodiment in section.

In this simple embodiment, a substrate (2) composed of a customary printed circuit board material such as FR-2, FR-3, FR-4, FR-4-Low-Tg, CEM-1, CEM-x, P1, CE, aramid and similar substrate materials with a conductor track structure (4, 5) produced on both sides is used and a functional element (3) is areally contact-connected by means of ultrasound or a friction welding process onto the at least two conductor track structures (4) depicted.

In a first embodiment, in this case the functional element (3) can be composed of copper or aluminum and in this case an intermetallic connection is usually produced with the conductor track structure (4) composed of copper.

In further embodiments of the present invention, the surfaces of the contact pairs (3, 4) can be coated chemically or electrolytically or by means of hot tin-plating (HAL). Given appropriate material pairing, an areal intermetallic connection is produced given a customary frequency range of a few kHz to above 30 kHz ultrasonic energy and given appropriate sonotrode embodiment and given appropriate contact pressure.

A high temperature required for the formation of the intermetallic contact is obtained only in a contact region comprising a depth of a few μm and, overall, the entire system does not experience a high degree of heating locally, such that virtually no thermal stresses occur by comparison with spot welding connections and the connection partners have a planarity even after the connection process.

With the use of enamel-insulated functional elements (3) an intermetallic contact layer (6) can be achieved given a specific embodiment of the contact partners (3, 4) and given appropriate embodiment of the enamel layer. However, it is also possible for the contact areas to be mechanically and/or chemically freed of a relevant insulation layer. Grinding methods, brushing methods, milling methods or an etching method or a plasma method or a UV laser method can be used in this case.

In present FIG. 1, the functional element (3) is represented as a connection element between two elements of the conductor track structure (4). In principle, even further conductor track structures (4) can be contact-connected and/or further conductor track structures (4) can also be arranged below the functional element (3). In this case, such elements can be covered with an insulating polymeric layer or the functional element (3) can be formed in insulating fashion in regions. Transpositions can thereby be formed.

In a further embodiment of the invention, the functional element (3) can be used as a piece element having the desired geometrical dimensioning or the element (3) can be supplied by a roll and, if appropriate, be cut to length by a suitable embodiment of the sonotrode during the contact-connecting process.

Optionally, after the contact-connecting and placement process it is also possible to perform a calendering process in the form of calender rolling or a flat pressing process, such that the planarity is thereby increased in the case of critical products.

FIG. 2 shows a schematic illustration of a multifunctional printed circuit board (1) according to the invention comprising a functional element (3) in an inner layer (7) in section. The substrate (7) is used for embedding during the laminating process, such that a substantially uniformly thick and planar printed circuit board (1) is achieved. In this FIG. 2, only one functional element (3) is illustrated above an element of a wiring structure (10) with the intermetallic connection layer (6). In a manner similar to that illustrated schematically in FIG. 1, the functional element (3) can also cross over conductor track structures and elements (3) can also be arranged in the substrate levels (2, 8, 9) or on the conductor track structures (4, 5, 10, 11, 12). The contact-connection of such functional elements (3) can be effected by passage openings or blind holes onto a contact area (4, 12) or by milling free or laser treatment.

FIG. 3 shows a schematic illustration of a multifunctional printed circuit board (1) according to the invention comprising two functional elements (3) in section. Two functional elements (3) are illustrated in this multilayer printed circuit board (1), said functional elements being embedded into the substrates (2, 8). In this specific embodiment, the elements (3) are contact-connected onto the rear side of a copper film by means of ultrasound or friction welding.

The copper films are pressed together by means of prepregs in a laminating process and subsequently structured by means of structuring processes that are customary in the printed circuit board industry. The conductor track structures (4, 12) are thereby produced, wherein the elements (3) are arranged internally above intermetallic areal contacts (6).

In this method, the elements (3) are not contact-connected onto already structured conductor track elements (4, 12) by means of ultrasound or friction welding, but rather onto whole-area copper films that are structured after the laminating process with insulating interlayers (substrates (2, 8)). A core layer (7) is additionally used in this embodiment.

FIG. 4a shows a schematic illustration of a multifunctional printed circuit board (1) according to the invention comprising functional elements (3, 22) in an oblique view. In this embodiment variant, the functional element (3)—as described in FIG. 3—is embodied internally. It is thus firstly contact-connected onto an as yet unstructured copper film by means of ultrasound via intermetallic areas (6) and then laminated and subsequently structured and the conductor track structures (4) are thus produced.

This illustration shows a passage opening (21) with which a further functional element (22) is contact-connected via a conductor track structure (10) and is thus wired with the structure (4).

FIG. 4b shows a schematic illustration of a multifunctional printed circuit board (1) according to the invention comprising functional elements (3, 22) in a plan view, wherein the elements (3, 10, 22) depicted by dashed lines are internal. The element (3) is usually led as far as the contact pads of the conductor track structure (4) since it is only by this means that correspondingly high currents are possible without significant heating of the electrically conductive wiring structures.

However, it is also possible to combine thick elements (3) with laterally wide conductor track structures (4), wherein the active copper cross section is intended to be similar for both structures (3, 4) and a similarly good current-carrying capacity is thus ensured.

This involves an internal electrical connection which enables high current flows and is embodied in crossing fashion. Therefore, the relatively high current flow can be passed to different locations of the printed circuit board with low power losses and low thermal loading. Since the high-current-carrying conductor track sections that cross one another are concealed and incorporated in inner layers, they are protected against any external influences and thereby placed in a manner free of damage.

Space for a fine wiring which would otherwise not be possible is thus created on the other levels, in particular the overlying levels.

FIG. 5 shows a schematic illustration of a multifunctional printed circuit board (1) according to the invention comprising functional elements (3, 22, 23) in section. The diverse possibilities for the arrangement of functional elements (3, 22, 23) are intended to be illustrated in this view.

Here elements which are arranged offset with respect to one another at two levels and are arranged in additional layers are placed in the form of current-carrying round wires 22, 23. The round wires 22, 23 are electrically conductively connected in a manner making mutual contact via an intermetallic connection.

These elements (22) are connected via intermetallic areas (6) to the conductor track structures (10, 11) and via a passage opening (21) to the conductor track structures (4, 12) and are thus connected to the functional elements (3, 23) via an intermetallic area (6) in the upper region of the printed circuit board (1).

The high-current-carrying elements can therefore also be routed in a plurality of mutually separated layers in the printed circuit board construction. This enables a high complexity of the printed circuit board construction with a smaller number of layers.

FIG. 6 shows a schematic illustration of a multifunctional printed circuit board (1) according to the invention comprising a functional element (3) with a mounted component (16) in section. FIG. 6 shows the contact-connection of a component (16) via a thermal contact-connecting area (17) to the surface of a functional element (3).

In this case, a cavity (15) is produced into the printed circuit board (1) by means of milling or laser treatment. In the case depicted, the cavity is produced completely as far as the element (3). However, it can also be produced just in piecewise fashion. The contact-connection (17) of good thermal conductivity can be embodied in electrically conductive or insulating fashion. It can be produced in detachable fashion by means of thermal conductive pastes or it can be produced such that it is detachable with difficulty by means of thermal conductive adhesive or a soldering paste by means of a soldering process.

The uncovered surface of the element (3) can also be covered by means of chemical or electrolytic processes or by means of pastes or by means of hot air tin-plating and the component (16) can then be mounted by means of the respectively optimum contact-connecting method.

The electrical connections of the component (16) are not depicted. They can be embodied by means of SMT (surface mount technology) or wire bonding techniques and similar technologies.

In this embodiment, a potting compound (19) is furthermore illustrated schematically, wherein the potting compound (19) can also be arranged completely over the component (16) and can be made largely transparent in the case of an optoelectronic function.

The functional element (3) can also be made significantly larger than the component (16) and thereby bring about a good heat dissipation. The printed circuit board (1) is provided with a soldering resist mask (13, 14) in this embodiment according to the prior art.

FIG. 6 reveals that the functional element (3) has a double function. Firstly, it serves for conducting high currents conducted over the entire cross section of this functional element 3, and, secondly, it simultaneously serves as it were as an inner cooling area which takes up and distributes particularly well the heat from said component 16 seated there.

In another configuration of this embodiment it may also be provided that said functional component 3 serves only and exclusively for thermally taking up the heat output from the component 16 and does not perform an additional function of increased current conduction.

FIG. 7 shows a schematic illustration of a multifunctional printed circuit board (1) according to the invention comprising a functional element (3) with a cavity (15, 18) on both sides, in section.

In this embodiment, an internal functional element (3) is embedded in the substrate layer (7), said element being connected via intermetallic contact areas (6) to the conductor track structuring (10). In this case, cavities (15, 16) are produced from above and from below. In principle, it is attempted to produce a good thermal and/or electrical contact to the element (3). This can be done by at least piecewise uncovering of the surfaces of the element (3). Schematic FIG. 7 also illustrates a covering of the surfaces of the element (3), but this does not result in a typical embodiment.

Depending on the type of components to be used, the latter can be mounted onto the upper or the lower area of the functional element (3) and a heat sink element can additionally or alternatively be mounted onto the opposite side. In principle, the element (3) can also be chosen to have a size such that a heat sink can be mounted on the same side.

In the exemplary embodiment shown, the functional element 3 serves as a rigid-flexible flexural element which makes it possible, once or with a small number of bending cycles, for the two printed circuit board sections that are connected by said functional element to be positioned at an angle relative to one another and to be left thus.

FIG. 8 shows a schematic illustration of a multifunctional printed circuit board (1) according to the invention comprising a functional element (3) with a cavity (18) on one side, in section. This embodiment with the cavity (18) represents a two-sided printed circuit board (1), wherein the surfaces are provided with soldering resist masks (13, 14). The cavity (18) is usually formed as far as the surface of the element (3), such that a best possible thermal contact-connection is possible.

FIG. 9 shows a schematic illustration of a multifunctional printed circuit board (1) according to the invention comprising a functional element (3) with a component (16) and a cavity (18) with an inserted heat sink (20), in section.

In this embodiment, a component (16) and a heat sink (20) are fixed by a thermal contact-connecting area (17) on the element (3). In principle, the component (16) can also be arranged in the cavity (18), and the heat sink (20) on the upper side of the element (3). In this case, too, the cavity (18) is formed usually and at least in piecewise fashion as far as the element (3), such that a best possible thermal contact is provided.

### LIST OF REFERENCE SYMBOLS

1 Multifunctional printed circuit board comprising at least one functional element
2 Substrate: base material e.g. FR-2, FR-3, FR-4, FR-4-Low-Tg, CEM-1, CEM-x, P1, CE, aramid, etc. or prepreg
3 Functional element: round or rectangular or strip-shaped; copper or aluminum or of good electrical and/or thermal conductivity
4 Conductor track structure: e.g. etched copper
5 Conductor track structure underside
6 Intermetallic connection: US or friction welding
7 Substrate 2: e.g. inner layer or core layer
8 Substrate 3: e.g. inner layer or core layer
9 Substrate 4: e.g. outer layer or prepreg
10 Conductor track structure internal
11 Conductor track structure internal
12 Conductor track structure external
13 Solder mask or soldering resist mask top
14 Solder mask or soldering resist mask bottom
15 Cavity top
16 Component
17 Thermal contact-connection (incl. mechanical fixing/mounting)
18 Cavity bottom
19 Potting compound
20 Heat sink
21 Plated-through hole or passage opening
22 Functional element crossed on core layer
23 Functional element crossed on copper film

1. A multifunctional printed circuit board (1) comprising an electrically conductive structure (4, 5, 10, 11, 12), wherein one or a plurality of high-current-carrying elements (3, 22, 23) is or are mechanically and electrically conductively fixed at least in piecewise fashion on the electrically conductive structure (4, 5, 10, 11, 12) by means of ultrasound or friction welding, characterized in that the functional element (3, 22, 23) is embodied as a thermal contact element for a component (16), wherein the piecewise contact (6) between the element (3, 22, 23) and the structure (4, 10, 11, 12) is embodied in intermetallic and areal fashion.

2. The multifunctional printed circuit board as claimed in claim 1, characterized in that the functional element (3, 22, 23) is composed of copper or aluminum and has a round or rectangular or rounded cross section.

3. The multifunctional printed circuit board (1) as claimed in claim 1, characterized in that the functional element (3, 22, 23) is composed of copper or aluminum and is provided with an electrically conductive and/or insulating surface coating.

4. The multifunctional printed circuit board (1) as claimed in claim 1, characterized in that the functional element (3, 22, 23) is composed of copper or aluminum and the surface is provided with at least one additional layer electrolytically or chemically.

5. The multifunctional printed circuit board (1) as claimed in claim 1, characterized in that the functional element (3, 22, 23) is composed of copper or aluminum and the surface is enamel-insulated at least in piecewise fashion.

6. The multifunctional printed circuit board (1) as claimed in claim 1, characterized in that the functional element (3, 22, 23) is composed of copper or aluminum and the surface is enamel-insulated at least in piecewise fashion and such electrically conductive structures (4, 5, 10, 11, 12) can cross without electrical contact-connection, or in that the functional elements (3, 22, 23) can be crossed with one another without electrical contact-connection.

7. The multifunctional printed circuit board (1) as claimed in claim 6, characterized in that the functional element (3, 22, 23) is composed of copper or aluminum and the enamel insulation is removed at least in the region of the connections (6) mechanically or thermally or chemically by means of grinding or brushing or flame treatment or plasma treatment or UV laser irradiation or treatment with a solvent.

8. The multifunctional printed circuit board (1) as claimed in claim 1, characterized in that the functional element (3, 22, 23) is able to conduct currents up to 100 amperes.

9. The multifunctional printed circuit board (1) as claimed in claim 1, characterized in that the printed circuit board (1) is embodied as a rigid or semiflexible or rigid-flexible printed circuit board.

10. The multifunctional printed circuit board (1) as claimed in claim 1, characterized in that the printed circuit board (1) is embodied as a one-sided or two-sided printed circuit board or as a multilayer printed circuit board.

11. The multifunctional printed circuit board (1) as claimed in claim 1, characterized in that the functional element (3, 22, 23) is embodied as. a thermal contact element for a component (16) and is milled free from the underside or the top side or from both sides and on one side the component (16) and on the other side the heat sink (20) are contact-connected with good thermal conductivity and the corresponding cavity (15, 18) is produced at least in punctiform fashion as far as the at least one functional element (3, 22, 23).

12. A method for producing a multifunctional printed circuit board (1) as claimed in claim 1, wherein first an etching-technological conductor track structure (4, 5, 10, 11, 12) is produced and then at least one functional element (3, 22, 23) is electrically conductively areally contact-connected by means of friction welding or ultrasonic welding (US welding) at least in piecewise fashion with the surface of a conductor track element (4, 5, 10, 11, 12), characterized in that at least one functional element (3, 22, 23) is electrically conductively areally contact-connected by means of friction welding or ultrasonic welding (US welding) at least in piecewise fashion on the surface of an as yet unstructured copper film and is then pressed in a laminating press according to the prior art to form a printed circuit board or to form a prepreg and the copper film is subsequently provided with structures (4, 5, 10, 11, 12).

13. The method for producing a multifunctional printed circuit board (1) as claimed in claim 12, characterized in that the surfaces (3, 22, 23, 4, 5, 10, 11, 12), by means of the friction welding or ultrasonic connection parameters, form an intermetallic connection with an electrically and thermally conductive and mechanically areal contact location (6).

14. The application of a multifunctional printed circuit board (1) as claimed in claim 1, as a wiring element which, on at least one wiring level, combines a circuit capable of conducting high currents.

15. The application of a multifunctional printed circuit board (1) as claimed in claim 1, as a wiring element which, through the integration of at least one functional element (3, 22, 23), increases the dissipating of heat from a component (16) mounted thereon.
